(19) United States
(12) Patent Application Publication
(10) Pub. No.: US 2016/0368030 A1
(43) Pub. Date: Dec. 22, 2016

(54) LIQUID CHEMICAL SUPPLYING SYSTEM, SUBSTRATE PROCESSING SYSTEM, AND SUBSTRATE PROCESSING METHOD

(71) Applicant: SAMSUNG ELECTRONICS CO., LTD., Suwon-si (KR)

(72) Inventors: Ingi KIM, Hwaseong-si (KR); Kyoung Hwan KIM, Yongin-si (KR); SeokHoon KIM, Seongnam-si (KR); Sang Won BAE, Suwon-si (KR); Jung-Min OH, Incheon (KR); Kuntack LEE, Suwon-si (KR); Hyosan LEE, Hwaseong-si (KR)

(21) Appl. No.: 15/142,298

(22) Filed: Apr. 29, 2016

(30) Foreign Application Priority Data
Jun. 16, 2015 (KR) 10-2015-0085217

(51) Int. Cl. B08B 3/10; B01F 15/00; H01L 21/66; H01L 21/67; H01L 21/02; B08B 3/08; B08B 3/02

(52) U.S. Cl. CPC B08B 3/102; B08B 3/08; B01F 15/00344; B01F 15/0022; B08B 3/02; H01L 21/67051; H01L 21/02057; H01L 22/26; B01F 2215/004

(57) ABSTRACT

Disclosed is a substrate processing system including a nozzle to supply a chemical solution containing a mixture of first and second solutions onto a substrate loaded on a supporter of a process chamber, a chemical solution supplying system to supply the chemical solution to the nozzle, and a controller to control the chemical solution supplying system. The chemical solution supplying system may include a mixing tank mixing a plurality of chemicals to produce the first solution, a supply tank receiving the first solution from the mixing tank and producing the chemical solution, a connection line to connect the mixing tank to the supply tank, and a valve and a pump on the connection line. The pump is controlled to allow the first solution to be supplied into the supply tank at a predetermined supply amount per stroke.

### CROSS-REFERENCE TO RELATED APPLICATIONS

This U.S. non-provisional patent application claims priority under 35 U.S.C. §119 to Korean Patent Application No. 10-2015-0085217, filed on Jun. 16, 2015, in the Korean Intellectual Property Office, the entire contents of which are hereby incorporated by reference.

### BACKGROUND

Example embodiments relate to a chemical solution supplying system, a substrate processing system including the same, and a method of processing a substrate using the same, and in particular, to a system and a method of mixing and supplying at least two chemicals.

Contaminant materials (e.g., particles, organic contaminants, and metallic contaminants) remaining on a surface of a substrate may lead to deterioration in electric characteristics and production yield of a semiconductor device. To remove the contaminant materials from the surface of the substrate, a cleaning process is performed before and/or after each unit operation of the semiconductor fabrication process. In general, the cleaning process may include a chemical treatment operation of removing metallic materials, organic materials, or particles from the substrate using chemicals. In the chemical treatment operation, a chemical solution supplying system is used to supply chemical solutions on the substrate. If several chemicals are mixed in the chemical solution, there may cause technical difficulties, such as non-uniform mixing of the chemicals or occurrence of precipitates.

### SUMMARY

Example embodiments provide a substrate processing system, which is configured to create chemical solution with stably mixed chemicals and to supply the chemical solution on a substrate, and a substrate processing method using the same.

Other example embodiments provide a substrate processing system with improved cleaning ability and a substrate processing method using the same.

According to example embodiments, a substrate processing system may include a process chamber, a supporting unit disposed in the process chamber to support a substrate, a nozzle unit configured to supply a chemical solution containing a mixture of first and second solutions onto the substrate loaded on the supporting unit, a chemical solution supplying system supplying the chemical solution to the nozzle unit, and a controller controlling the chemical solution supplying system. The chemical solution supplying system may include a mixing tank, in which a plurality of chemicals may be mixed to produce the first solution, a supply tank configured to receive the first solution from the mixing tank, to mix the first solution with the second solution to produce the chemical solution, and to supply the chemical solution to the nozzle unit, a connection line connecting the mixing tank to the supply tank, and an on/off valve and a pump provided on the connection line. The controller controls the pump to allow the first solution to be supplied into the supply tank at a predetermined supply amount per stroke.

In some embodiments, when a total amount of the first solution supplied into the supply tank reaches a predetermined amount, the controller controls the on/off valve to terminate the supply of the first solution.

In some embodiments, the plurality of chemicals may include a first chemical and a second chemical, the chemical solution supplying system may further include a first chemical supply source supplying the first chemical to the mixing tank, a second chemical supply source supplying the second chemical to the mixing tank, a circulation line connected to the mixing tank and used to circulate the first solution, and a concentration meter provided on the circulation line, and the controller controls the first chemical supply source, the second chemical supply source, and the concentration meter to allow the first solution to have a concentration within a predetermined concentration range.

In some embodiments, when the concentration of the first solution may be within the predetermined concentration range, the controller controls the on/off valve and the pump to supply the first solution to the supply tank.

In some embodiments, the chemical solution supplying system may further include a chemical solution supply line connecting the supply tank to the nozzle unit, and a thermostatic bath provided on the chemical solution supply line to control temperature of the chemical solution, and the thermostatic bath may be provided to have an explosion-proof structure.

In some embodiments, the predetermined supply amount per stroke ranges from 5 cc to 20 cc.

In some embodiments, the first solution may be an acid solution and the second solution may be an organic solvent.

In some embodiments, the supply tank may include a housing, and a coating layer provided in the housing to prevent the housing from being damaged by the chemical solution.

In some embodiments, the supply tank may include a first supply tank and a second supply tank.

In some embodiments, the pump may include a constant flow rate pump.

In some embodiments, the pump may be disposed adjacent to the mixing tank.

According to example embodiments, a substrate processing method may include supplying a plurality of chemicals to a mixing tank, mixing the chemicals to produce a first solution, supplying the first solution from the mixing tank to a supply tank, mixing the first solution with a second solution in the supply tank to produce a chemical solution, and supplying the chemical solution to a nozzle unit to process a substrate. Supplying the first solution to the mixing tank may include controlling a supply amount per stroke of a constant flow rate pump provided on a connection line connecting the mixing tank to the supply tank.

In some embodiments, supplying the first solution to the supply tank may include terminating supplying the first solution, when a total amount of the first solution supplied to the supply tank reaches a predetermined amount.

In some embodiments, supplying the first solution to the supply tank may further include draining the chemicals from the mixing tank, when the total amount of the first solution supplied to the supply tank reaches a predetermined amount.

In some embodiments, producing the first solution may include circulating the chemicals along a circulation line connected to the mixing tank and measuring and correcting a concentration of the first solution using a concentration meter provided on the circulation line.

In some embodiments, supplying the first solution to the supply tank may be performed when the concentration of the first solution reaches a predetermined concentration range.

In some embodiments, when the concentration of the first solution is beyond the predetermined concentration range, an interlock may be produced to terminate supplying the first solution.

In some embodiments, the predetermined supply amount per stroke may range from 5 cc to 20 cc.

In some embodiments, the first solution may be an acid solution and the second solution may be an organic solvent.

According to example embodiments, a chemical solution supplying system configured to mix a first solution, which has low solubility with respect to a second solution, with the second solution and to supply a chemical solution, which is produced from the mixing of the first and second solutions, to a substrate. The chemical solution supplying system may include a mixing tank, in which a plurality of chemicals are mixed to produce the first solution, a supply tank configured to receive the first solution from the mixing tank, to mix the first solution with the second solution to produce the chemical solution, and to supply the chemical solution to the substrate, a connection line connecting the mixing tank to the supply tank, an on/off valve and a constant flow rate pump provided on the connection line, and a controller controlling the mixing tank, the supply tank, the on/off valve, and the constant flow rate pump. The controller controls the constant flow rate pump to allow the first solution to be supplied to the supply tank at a predetermined supply amount per stroke.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a diagram illustrating a substrate processing system according to example embodiments.

FIG. 2 is an enlarged view of a chemical solution supplying system of FIG. 1.

FIG. 3 is a flow chart illustrating a substrate processing method according to example embodiments.

FIGS. 4 through 9 are diagrams sequentially illustrating operations of a substrate processing system, based on the substrate processing method of FIG. 3.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

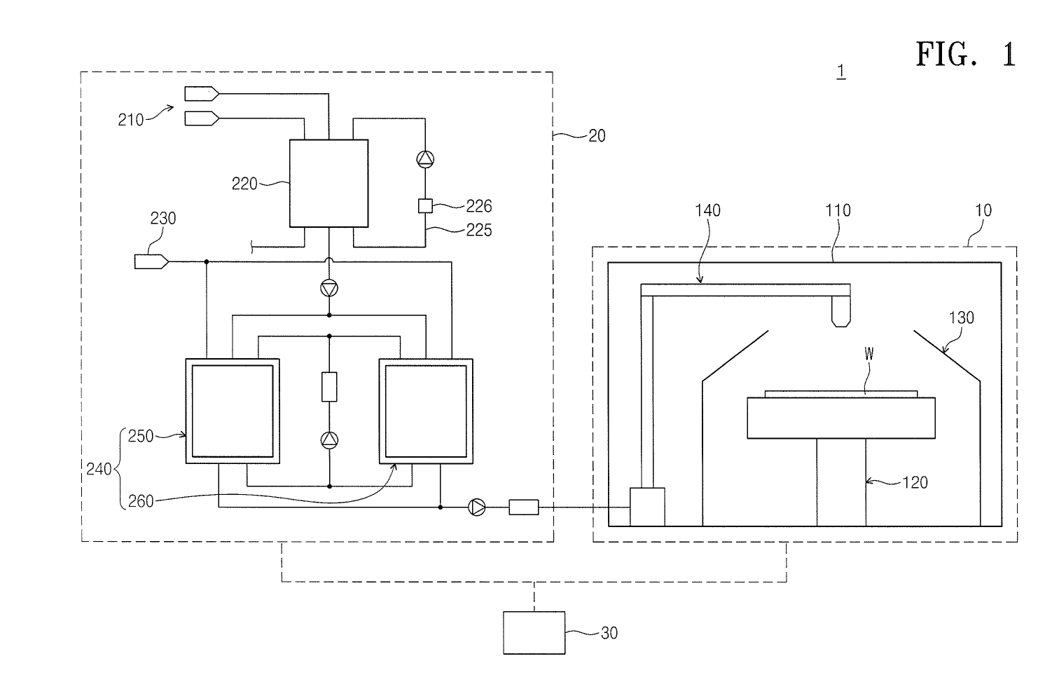

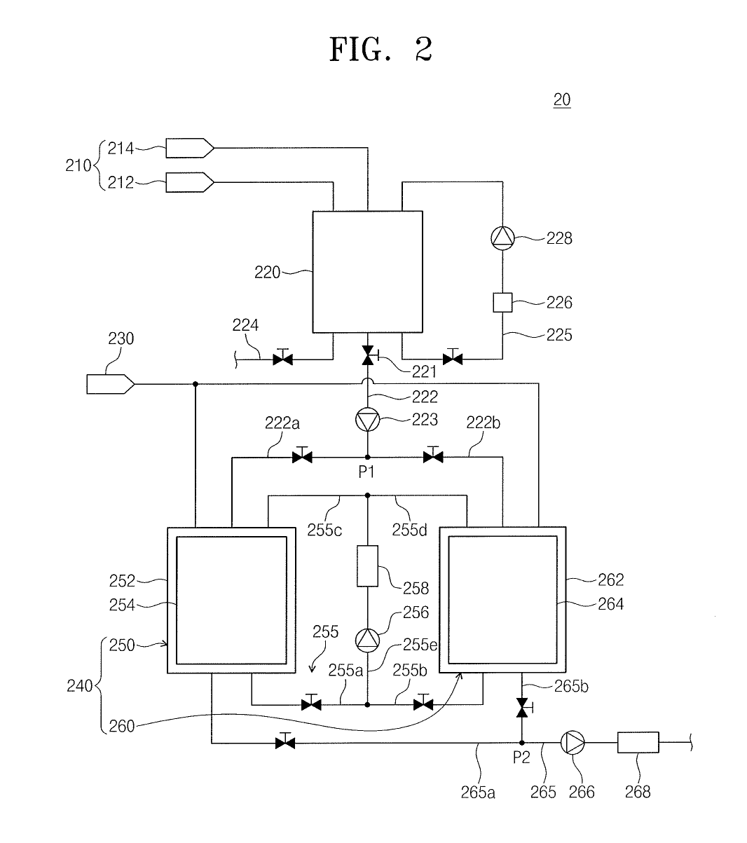

FIG. 1 is a diagram illustrating a substrate processing system 1 according to example embodiments, and FIG. 2 is an enlarged view of a chemical solution supplying system 20 of FIG. 1. Referring to FIGS. 1 and 2, the substrate processing system 1 may include a process chamber 10, a chemical solution supplying system 20, and a controller 30.

The process chamber 10 may include a housing 110, a supporting unit 120, a cup unit 130, and a nozzle unit 140. The process chamber 10 may be configured to perform a substrate processing process, in which chemical solution is supplied onto a substrate or wafer W. As an example, the process chamber 10 may be used to perform a cleaning process on the substrate W.

The housing 110 may provide a space for the substrate processing process. The supporting unit 120 may be provided in the housing 110. A top surface of the supporting unit 120 may be configured to support the substrate W. The supporting unit 120 may also be configured to rotate the substrate W. The cup unit 130 may be provided to enclose the supporting unit 120. The rotation of supporting unit 120 may result in an outward scattering or blowing of the chemical solution, and the cup unit 130 may be configured to collect the blown part of the chemical solution. When the substrate processing process is performed, the nozzle unit 140 may supply the chemical solution to the substrate W.

In some embodiments, the chemical solution may be or contain a mixture of first and second solutions. The first solution may be a chemical-containing acid solution. The first solution may be an acid solution, in which a plurality of chemicals are mixed. As an example, the first solution may be an acid solution, in which a first chemical and a second chemical are mixed. The second solution may be an organic solvent. Since the acid solution has low solubility with respect to an organic solvent, precipitates may be produced when the first and second solutions are mixed with each other. As an example, metallic precipitates may be produced. The precipitates may function as particles affecting a substrate processing process. As an example, the first solution may be or contain a low ammonium fluoride liquid (LAL) containing hydrogen fluoride (HF) and ammonium fluoride (NH₄F), the second solution may be or contain isopropyl alcohol (IPA). Alternatively, at least one of the first and second solutions may contain a material causing production of precipitates, when they are mixed with each other.

Referring to FIGS. 1 and 2, the chemical solution supplying system 20 may include a chemical supply source 210, a mixing tank 220, an organic solvent supply source 230, a connection line 222, a first circulation line 225, an exhausting line 224, a supply tank 240, a second circulation line 255, and a chemical solution supply line 265. The chemical solution supplying system 20 may supply a chemical solution to the nozzle unit 140.

The chemical solution supplying system 20 may include a plurality of the chemical supply sources 210. As an example, as shown in FIGS. 1 and 2, the chemical supply source 210 may include a first chemical supply source 212 and a second chemical supply source 214. The first chemical supply source 212 may contain a first chemical to be supplied into the mixing tank 220. The second chemical supply source 214 may contain a second chemical to be supplied into the mixing tank 220. In some embodiments, the first chemical may be LAL solution, and the second chemical may be de-ionized water (DIW). Alternatively, the chemical supply source 210 may include three or more chemical supply sources. Each of the chemical supply sources 212 and 214 may be configured to supply chemical contained therein to the mixing tank 220.

In the mixing tank 220, a plurality of chemicals may be mixed to produce a first solution. The first circulation line 225 may be connected to the mixing tank 220. A concentration meter 226 and a first circulation pump 228 may be provided on the first circulation line 225. If first and second chemicals are supplied into the mixing tank 220, they may circulate through the first circulation line 225 and may be mixed to produce a first solution. The concentration meter 226 may be configured to measure concentration of the first solution circulating through the first circulation line 225. The substrate processing system 1 may be configured to allow the concentration of the first solution measured by the concentration meter 226 to be within a predetermined concentration range. As an example, the predetermined concentration range may be selected in such a way that a ratio of the first chemical to the second chemical ranges from 1:3 to 1:8. For example, the predetermined concentration range may be selected in such a way that a ratio of the first chemical to the second chemical ranges from 1:4.5 to 1:5.5. Here, the first chemical may be LAL solution, and the second chemical may be de-ionized water. The first circulation pump 228 may be configured to allow the first solution to circulate through the first circulation line 225 at a smooth flow rate.

The exhausting line 224 may be connected to the mixing tank 220. When the supply of the first solution is completed, the first solution may be drained from the mixing tank 220 through the exhausting line 224. In some example embodiments, when the concentration of the first solution is not within the predetermined concentration range, the first solution may be drained from the mixing tank 220 through the exhausting line 224.

The connection line 222 may be used to connect the mixing tank 220 to the supply tank 240. The connection line 222 may supply the first solution contained in the mixing tank 220 to the supply tank 240. The connection line 222 may be divided into a first connection line 222a and a second connection line 222b, at a first branch point P1. The first connection line 222a may be connected to a first supply tank 250, and the second connection line 222b may be connected to a second supply tank 260. An on/off valve 221 and a supply pump 223 may be provided on the connection line 222. The on/off valve 221 may control an on/off state of the connection line 222 or the flow rate of the first solution flowing through the connection line 222. In the case where the concentration of the first solution is within the predetermined concentration range, the on/off valve 221 may be opened to supply the first solution to the supply tank 240.

The supply pump 223 may control a supply amount of the first solution to be supplied through the connection line 222. The supply pump 223 may be disposed adjacent to the mixing tank 220. As an example, the supply pump 223 may be disposed in such a way that its distance from the mixing tank 220 is within a range from 30 cm to 70 cm. The supply pump 223 may be configured to realize a uniform supply amount per stroke. The supply pump 223 may also be configured to minutely adjust a supply amount per stroke. As an example, the supply pump 223 may be configured to realize a supply amount ranging from 3 cc per stroke to 50 cc per stroke. Alternatively, the supply pump 223 may be configured to realize a supply amount ranging from 5 cc per stroke to 20 cc per stroke. As an example, the supply pump 223 may be a constant flow rate pump. In some embodiments, a small amount of the first solution may be sequentially supplied into the mixing tank 220, and the first solution may be sequentially mixed with the second solution in the supply tank 240. Thus, even when the first solution has low solubility with respect to the second solution, it is possible to stably mix the first solution with the second solution. For example, it is possible to prevent precipitates from being formed in the mixing tank 220 and to prevent a hunting issue in etch rate from occurring.

The first solution supplied from the mixing tank 220 may flow into the supply tank 240. Here, the supply tank 240 may contain the second solution, which may be supplied from the organic solvent supply source 230. The second solution may contain an organic solvent. As an example, the organic solvent may be isopropyl alcohol (IPA). The first solution may be dissolved by the second solution contained in the supply tank 240 to produce chemical solutions. In the supply tank 240, the first solution and the second solution may be mixed to produce the chemical solution, and the chemical solution may be supplied to the nozzle unit 140 from the supply tank 240. The chemical solution may be an organic acid solution.

The supply tank 240 may include a plurality of tanks. As shown in FIGS. 1 and 2, the supply tank 240 may include the first supply tank 250 and the second supply tank 260. The first supply tank 250 may include a housing 252 and a coating layer 254. The housing 252 may provide a room, in which the chemical solution can be contained. The coating layer 254 may be configured to prevent an inner part or surface of the housing 252 from being damaged by the chemical solution. The coating layer 254 may be formed of or include, for example, polytetrafluoroethylene (PTFE) (e.g., Teflon). This may prevent corrosion caused by an organic acid. The second supply tank 260 may be configured to have substantially the same features as those of the first supply tank 250. Thus, a detailed description thereof will be omitted.

Each of the first and second supply tanks 250 and 260 may be configured to mix the first and second solutions, thereby forming the chemical solution, and to store the chemical solution. The first and second supply tanks 250 and 260 may be configured to function as a preparatory substitute for each other. As an example, when the chemical solution is supplied to the nozzle unit 140 from one of the first and second supply tanks 250 and 260, a process of exchanging the chemical solution may be performed in the other.

The second circulation line 255 may be connected to the supply tank 240. The second circulation line 255 may be connected to the supply tanks 250 and 260. The second circulation line 255 may include a first line 255a, a second line 255b, a third line 255c, a fourth line 255d, and a shared line 255e. The first and second solutions in the first and second supply tanks 250 and 260 may be circulated through the second circulation line 255 to produce the chemical solution. The first line 255a may be connected to a bottom surface of the first supply tank 250. The first line 255a may be used to drain the solution in the first supply tank 250. The second line 255b may be connected to a bottom surface of the second supply tank 260. The second line 255b may be used to drain the solution in the second supply tank 260. The third line 255c may be connected to a top surface of the first supply tank 250. The fourth line 255d may be connected to a top surface of the second supply tank 260. The shared line 255e may be provided to connect all of the first line 255a, the second line 255b, the third line 255c, and the fourth line 255d to each other. Solution flowing through the shared line 255e may again flow into the first supply tank 250 through the third line 255c or into the second supply tank 260 through the fourth line 255d. A second circulation pump 256 and a thermostatic bath 258 may be provided on the shared line 255e. The second circulation pump 256 may be used to expedite the circulation of the solution in the second circulation line 255. The thermostatic bath 258 may be configured to control temperature of the solution in the second circulation line 255. The thermostatic bath 258 may be an explosion-proof organic acid thermostatic bath. The first solution and the second solution mixed in the second circulation line 255 may form a chemical solution. Although not shown, a concentration meter may be provided on the second circulation line 555. As an example, a mixing ratio between the second solution, the first chemical, and the second chemical may be controlled to be within a range from 1:0.0001:0.001 to 1:0.001:0.01. For example, the mixing ratio between the second solution, the first chemical, and the second chemical may be about 1:0.00083:0.004.

The chemical solution supply line 265 may be provided to connect the supply tank 240 to the nozzle unit 140. The chemical solution supply line 265 may include a first chemical solution supply line 265a connecting the first supply tank 250 to a second branch point P2 and a second chemical solution supply line 265b connecting the second supply tank 260 to the second branch point P2. A chemical solution supply pump 266 and a thermostatic bath 268 may be provided on the chemical solution supply line 265. The chemical solution supply pump 266 may be controlled to adjust an amount of the chemical solution to be supplied to the nozzle unit 140. The thermostatic bath 268 may be configured to control temperature of the chemical solution. As an example, the thermostatic bath 268 may be an explosion-proof organic acid thermostatic bath.

Referring back to FIG. 1, the controller 30 may control the process chamber 10 and the chemical solution supplying system 20. For example, the controller 30 may control each of parts of the chemical solution supplying system 20 to allow for effective production and supply of the chemical solutions in the chemical solution supplying system 20.

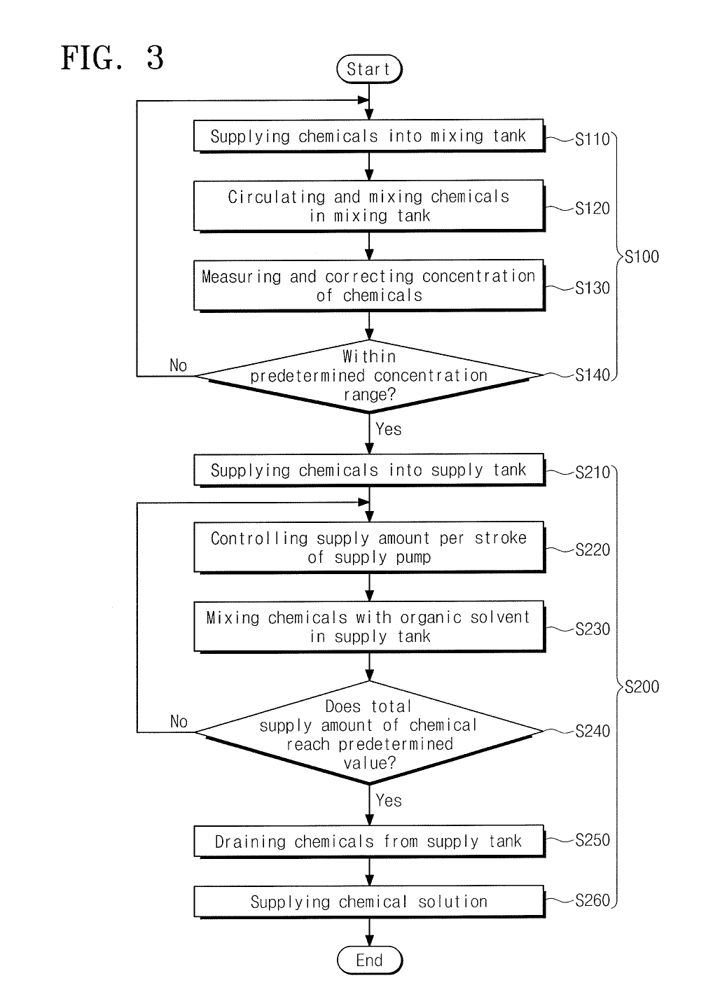

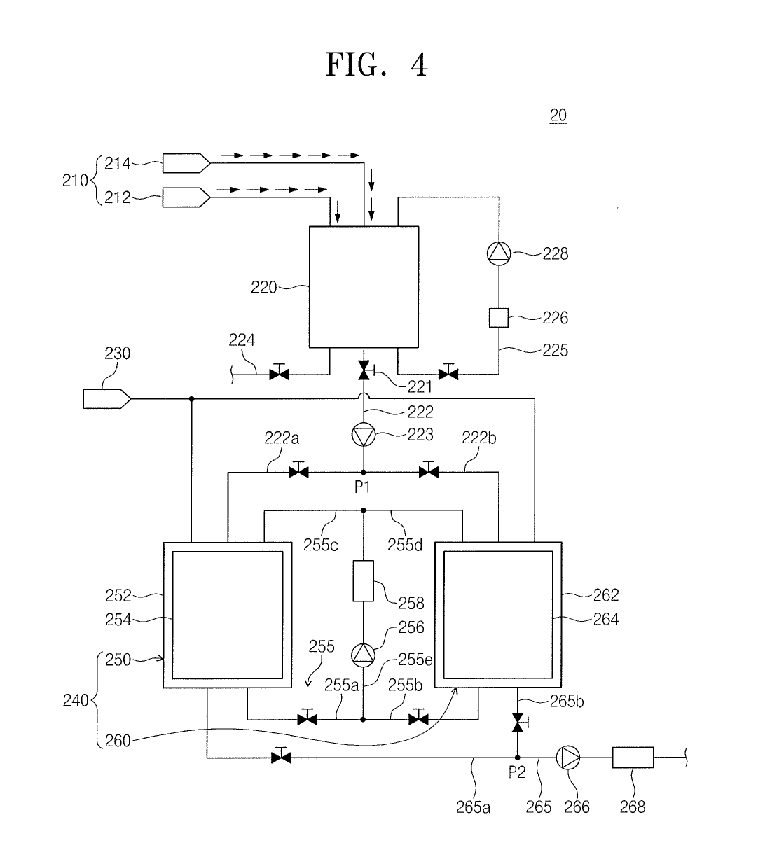

FIG. 3 is a flow chart illustrating a substrate processing method according to example embodiments. FIGS. 4 through 9 are diagrams sequentially illustrating operations of a substrate processing system, based on the substrate processing method of FIG. 3. Hereinafter, a substrate processing process of producing and supplying a chemical solution will be described with reference to FIGS. 3 through 9. In FIGS. 4 through 9, arrows depict the flow of fluid. An open and close state of a valve is illustrated by a depicted pattern of the valve; for example, a filled pattern represents that the valve is in a close state and an empty pattern represents that the valve is in an open state. The substrate processing process may include an operation S100 of producing the first solution and an operation 5200 of producing and supplying the chemical solution.

Referring to FIGS. 3 and 4, a plurality of chemicals may be supplied into the mixing tank 220 (in S110). The first chemical in the first chemical supply source 212 may be supplied into the mixing tank 220, and the second chemical in the second chemical supply source 214 may be supplied into the mixing tank 220. In some embodiments, the first chemical may be LAL solution, and the second chemical may be de-ionized water (DIW).

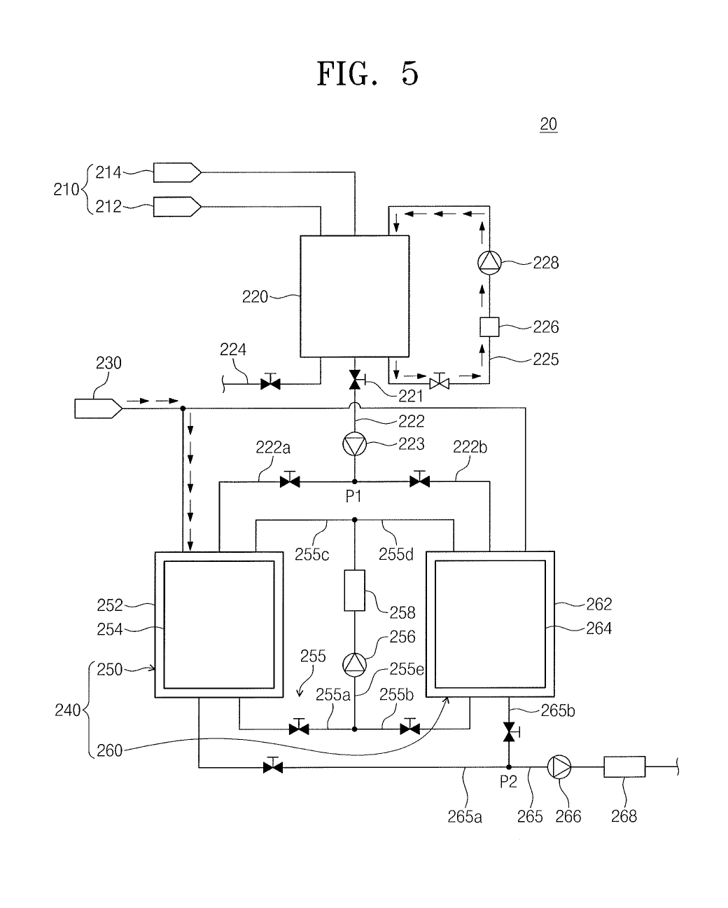

Referring to FIGS. 3 and 5, under the control of the controller 30, the first solution may be produced in the mixing tank 220. For example, the first solution may be produced by circulating solutions contained in the mixing tank 220 along the first circulation line 225 (in S120). The concentration meter 226 provided on the first circulation line 225 may be used to measure and correct concentration of the first solution passing through the first circulation line 225 (in S130). As an example, the predetermined concentration range may be selected in such a way that a ratio of the first chemical to the second chemical ranges from 1:3 to 1:8. In some embodiments, the predetermined concentration range may be selected to allow a ratio of the first chemical to the second chemical to be within a range of 1:4.5 to 1:5.5. If necessary, the controller 30 may control at least one of supply amounts of the first and second chemical supply sources 212 and 214, and this may make it possible for the ratio between the first chemical and the second chemical to meet the requirement of the predetermined concentration range. In the case where the concentration of the first solution is beyond the predetermined concentration range, the second solution in the organic solvent supply source 230 may be supplied into the first supply tank 250, under the control of the controller 30. The second solution may be an organic solvent. As an example, the organic solvent may be isopropyl alcohol (IPA).

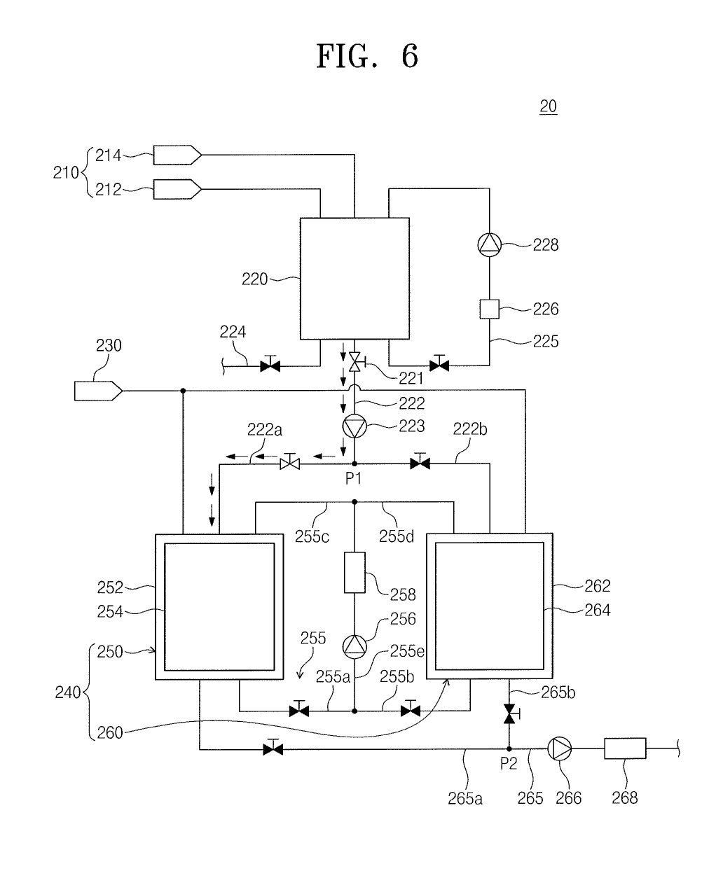

Referring to FIGS. 3 and 6, if the first solution is prepared to meet the requirement of the predetermined concentration range, the first solution may be supplied into the first supply tank 250, under the control of the controller 30 (in S140 and S210). Furthermore, under the control of the controller 30, the second solution in the organic solvent supply source 230 may be supplied into the first supply tank 250 and may be mixed with the first solution to produce the chemical solution. If the first solution is supplied into the first supply tank 250, the first solution may be solved by the second solution contained in the first supply tank 250. Here, the controller 30 may control the supply pump 223 to allow the supply pump 223 to be operated at a uniform supply amount per stroke (in S220 and S230). The controller 30 may control the supply pump 223 in such a way that the supply amount per stroke of the supply pump 223 is finely changed. As an example, the supply amount of the supply pump 223 may range from 3 cc per stroke to 50 cc per stroke. In some example embodiments, the supply pump 223 may be configured to realize a supply amount ranging from 5 cc per stroke to 20 cc per stroke. As an example, the supply pump 223 may be a constant flow rate pump. In some embodiments, a small amount of the first solution may be sequentially supplied and mixed with the second solution. Thus, even when the first solution has low solubility with respect to the second solution, it is possible to stably mix the first solution with the second solution. For example, it is possible to prevent precipitates from being formed in the first supply tank 250 and to prevent a hunting issue in etch rate. By contrast, in the case where the first solution is supplied at a flow rate higher than 50 cc per stroke, precipitates serving as particles may be formed in the supply tank 240.

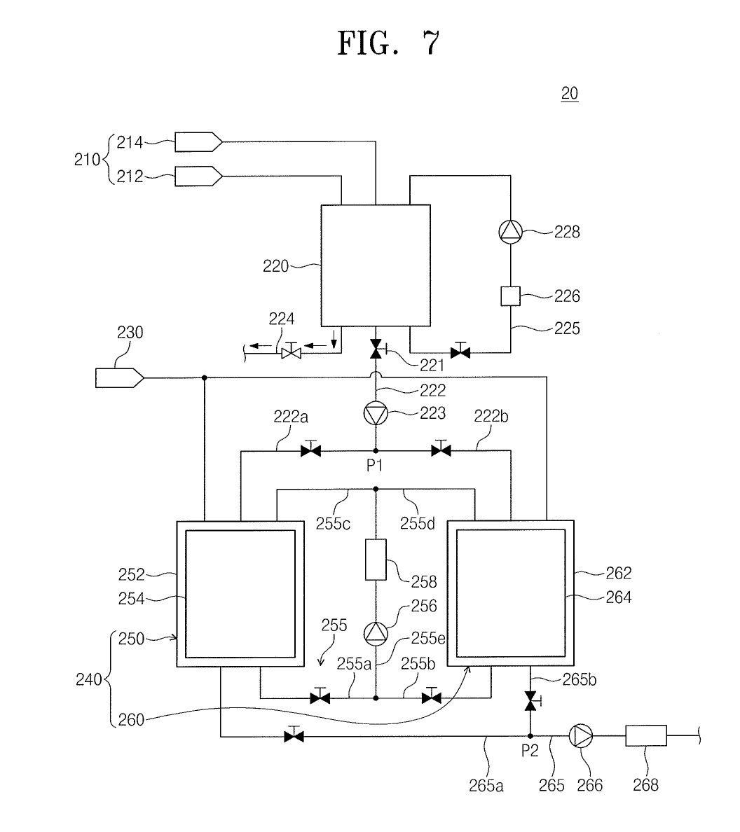

Referring to FIGS. 3 and 7, if the total amount of the first solution supplied into the first supply tank 250 reaches a predetermined amount, the on/off valve 221 may be closed to terminate the supply of the first solution, under the control of the controller 30. Here, the predetermined amount may be selected within a range capable of sufficiently solving the first solution with the second solution, without occurrence of precipitates. As an example, the predetermined amount may range from 30 ppm to 80 ppm. In some embodiments, the predetermined amount may be about 50 ppm. Under the control of the controller 30, the first solution remaining in the mixing tank 220 may be drained to the exhausting line 224 (in S240 and S250). In certain embodiments, if the concentration of the first solution is beyond the predetermined concentration range, the first solution may be drained to the exhausting line 224. This may allow the controller 30 to precisely control the concentration of the first solution.

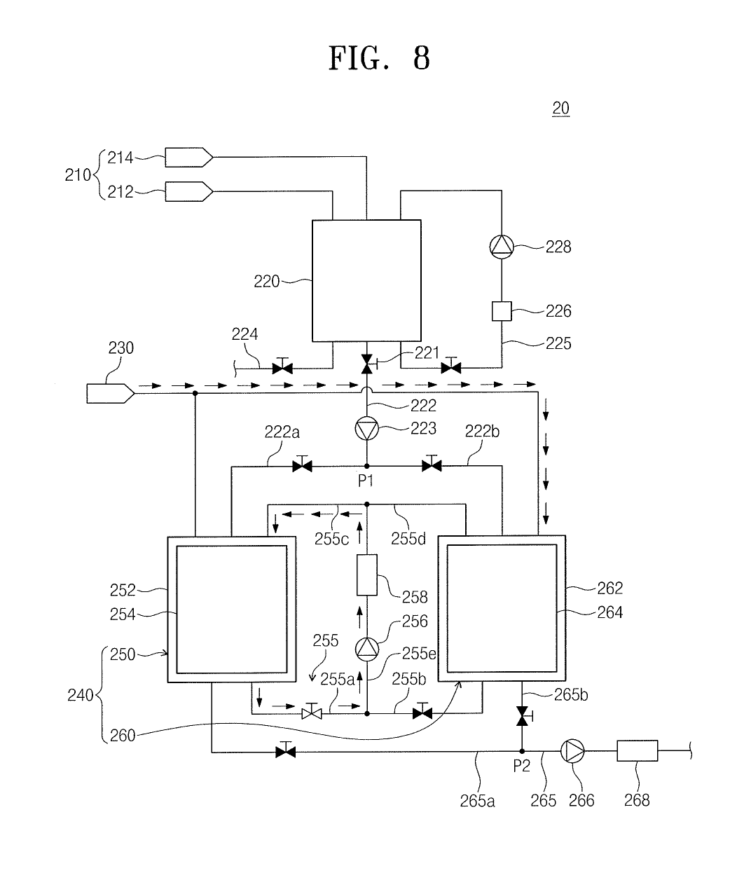

Referring to FIGS. 3 and 8, under the control of the controller 30, the chemical solution in the first supply tank 250 may be circulated along the second circulation line 255, and during the circulation of the chemical solution, the first and second chemicals may be mixed with each other. Here, the thermostatic bath 258 may be configured to control temperature of the chemical solution. The thermostatic bath 258 may be an explosion-proof organic acid thermostatic bath. Accordingly, it is possible to effectively reduce temperature dependence of an etch rate and supply the chemical solution with a uniform quality. In some embodiments, a mixing ratio between the second solution, the first chemical, and the second chemical may be controlled to be within a range from 1:0.0001:0.001 to 1:0.001:0.01. For example, the mixing ratio between the second solution, the first chemical, and the second chemical may be about 1:0.00083:0.004. Under the control of the controller 30, the second solution in the organic solvent supply source 230 may be supplied to the second supply tank 260.

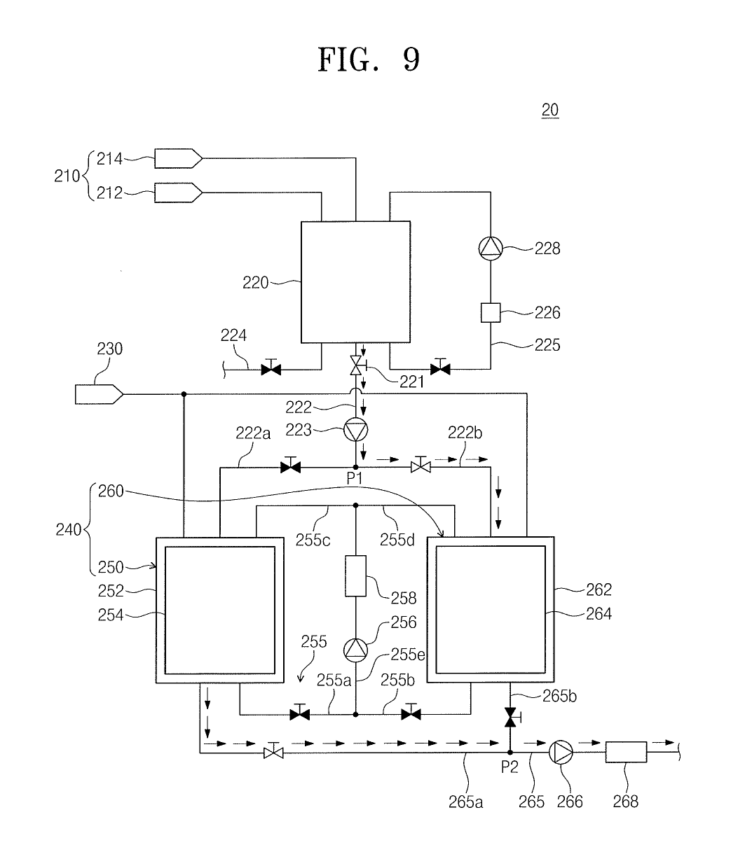

Referring to FIGS. 3 and 9, in the case where the chemical solution is prepared to have meet the requirement for parameters, such as concentration and temperature, the chemical solution may be supplied to the nozzle unit 140 through the first chemical solution supply line 265a (in S260). The temperature of the chemical solution in the first chemical solution supply line 265a may be controlled by the thermostatic bath 268. Here, the thermostatic bath 268 may be an explosion-proof organic acid thermostatic bath. Accordingly, it is possible to effectively reduce temperature dependence of an etch rate and to supply the chemical solution with a uniform quality. When the chemical solution in the first supply tank 250 is supplied to the nozzle unit 140, an exchanging operation of the chemical solution may be performed in the second supply tank 260. The first solution in the mixing tank 220 may be supplied to the second supply tank 260. Here, the concentration and temperature of the first solution may have values that have been controlled by the afore-described method described with reference to FIGS. 4 and 5. If the first solution is supplied into the second supply tank 260, the first solution may be solved by the second solution contained in the second supply tank 260. Here, the controller 30 may control the supply pump 223 to allow solution to flow through the connection line 222 at a uniform supply amount per stroke. The controller 30 may control the supply pump 223 in such a way that the supply amount per stroke thereof is finely changed. As an example, the supply amount of the supply pump 223 may range from 3 cc per stroke to 50 cc per stroke. Alternatively, the supply amount of the supply pump 223 may range from 5 cc per stroke to 20 cc per stroke. As an example, the supply pump 223 may be a constant flow rate pump. In some embodiments, a small amount of the first solution may be sequentially supplied and may be sequentially mixed with the second solution. Thus, even when the first solution has low solubility with respect to the second solution, it is possible to stably mix the first solution with the second solution. For example, it is possible to prevent precipitates from being formed in the mixing tank 220 and to prevent a hunting issue in etch rate from occurring. Thereafter, the chemical solution in the second supply tank 260 may be circulated along the second circulation line 255, and during the circulation of the chemical solution, the concentration and temperature of the chemical solution may be controlled. Since, in the operation of producing and supplying the chemical solution, the first and second supply tanks 250 and 260 are configured to function as a preparatory substitute for each other, it is possible to reduce a down time of the system for replacement of the chemical solution.

In order to reduce complexity in the drawings and to provide better understanding of example embodiments, the chemical solution supplying system 20 with the first and second supply tanks 250 and 260 has been described as an example of example embodiments, but example embodiments are not limited thereto. For example, it is possible to apply the embodiments to chemical solution supplying system with one tank or three or more tanks, in a manner similar to the afore-described case provided with two tanks.

Furthermore, a substrate cleaning process has been described as an example of a process of supplying chemical solution, but it is possible to apply the embodiments to any substrate processing process, in which mixed chemical solution is used. The chemical solution, which is produced by mixing the first and second solutions, has been described as an example of example embodiments, but example embodiments are not limited thereto. For example, if there is a concern about occurrence of precipitates, the number of the solutions to be used in the mixing may be changed.

According to example embodiments, by controllably supplying small amounts of chemicals, it is possible to sequentially dilute process solution. This may make it possible to stably produce a chemical solution, to suppress occurrence of precipitates or particles, and to improve process efficiency of a cleaning process.

While example embodiments have been particularly shown and described, it will be understood by one of ordinary skill in the art that variations in form and detail may be made therein without departing from the spirit and scope of the attached claims.

What is claimed is:

1. A substrate processing system, comprising:
a process chamber;
a supporter in the process chamber to support a substrate;
a nozzle to supply a chemical solution containing a mixture of first and second solutions onto the substrate loaded on the supporter;
a chemical solution supply system to supply the chemical solution to the nozzle; and
a controller to control the chemical solution supply system,
the chemical solution supply system including:
a mixing tank to produce the first solution by mixing a plurality of chemicals;
a supply tank to receive the first solution from the mixing tank, to mix the first solution with the second solution to produce the chemical solution, and to supply the chemical solution to the nozzle;
a connection line to connect the mixing tank to the supply tank; and
an on/off valve and a constant flow rate pump on the connection line,
the controller to control the constant flow rate pump to allow the first solution to be supplied into the supply tank at a predetermined supply amount per stroke.

2. The substrate processing system of claim 1, wherein, when a total amount of the first solution supplied into the supply tank reaches a predetermined amount, the controller controls the on/off valve to terminate the supply of the first solution.

3. The substrate processing system of claim 2, wherein:
the plurality of chemicals includes a first chemical and a second chemical,
the chemical solution supply system further includes:
a first chemical supply source to supply the first chemical to the mixing tank;
a second chemical supply source to supply the second chemical to the mixing tank;
a circulation line connected to the mixing tank to circulate the first solution; and
a concentration meter on the circulation line, and
the controller controls the first chemical supply source, the second chemical supply source, and the concentration meter to allow the first solution to have a concentration within a predetermined concentration range.

4. The substrate processing system of claim 3, wherein, when the concentration of the first solution is within the predetermined concentration range, the controller controls the on/off valve and the constant flow rate pump to supply the first solution to the supply tank.

5. The substrate processing system of claim 4, wherein the chemical solution supply system further includes:
a chemical solution supply line to connect the supply tank to the nozzle; and
a thermostatic bath on the chemical solution supply line to control temperature of the chemical solution, and
the thermostatic bath has an explosion-proof structure.

6. The substrate processing system of claim 1, wherein the predetermined supply amount per stroke ranges from 5 cc to 20 cc.

7. The substrate processing system of claim 1, wherein the first solution is an acid solution and the second solution is an organic solvent.

8. The substrate processing system of claim 7, wherein the supply tank includes:
a housing; and
a coating layer in the housing to prevent the housing from being damaged by the chemical solution.

9. The substrate processing system of claim 1, wherein the supply tank includes a first supply tank and a second supply tank.

10. The substrate processing system of claim 1, wherein the constant flow rate pump is adjacent to the mixing tank.

11. A chemical solution supply system to mix a first solution, which has low solubility with respect to a second solution, with the second solution and to supply a chemical solution, which is produced from the mixing of the first and second solutions, to a substrate, the chemical solution supply system including:
a mixing tank to produce the first solution by mixing a plurality of chemicals;
a supply tank to receive the first solution from the mixing tank, to mix the first solution with the second solution to produce the chemical solution, and to supply the chemical solution to the substrate;
a connection line to connect the mixing tank to the supply tank;
an on/off valve and a constant flow rate pump on the connection line; and
a controller to control the mixing tank, the supply tank, the on/off valve, and the constant flow rate pump,
the controller to control the constant flow rate pump to allow the first solution to be supplied to the supply tank at a predetermined supply amount per stroke.

12. The chemical solution supply system of claim 11, wherein, when a total amount of the first solution supplied into the supply tank reaches a predetermined amount, the controller controls the on/off valve to terminate the supply of the first solution.

13. The chemical solution supply system of claim 12, wherein:
the plurality of chemicals includes a first chemical and a second chemical,
the chemical solution supply system further includes:
a first chemical supply source to supply the first chemical to the mixing tank;
a second chemical supply source to supply the second chemical to the mixing tank;
a circulation line connected to the mixing tank to circulate the first solution; and
a concentration meter on the circulation line, and
the controller controls the first chemical supply source, the second chemical supply source, and the concentration meter to allow the first solution to have a concentration within a predetermined concentration range.

14. The chemical solution supply system of claim 13, wherein, when the concentration of the first solution is within the predetermined concentration range, the controller controls the on/off valve and the constant flow rate pump to supply the first solution to the supply tank.

15. The chemical solution supply system of claim 14, wherein the predetermined supply amount per stroke ranges from 5 cc to 20 cc.

16. A substrate processing method, the method comprising:
supplying a plurality of chemicals to a mixing tank;
mixing the chemicals to produce a first solution;
supplying the first solution from the mixing tank to a supply tank;
mixing the first solution with a second solution in the supply tank to produce a chemical solution; and
supplying the chemical solution to a nozzle to process a substrate,
supplying the first solution to the mixing tank including controlling a supply amount per stroke of a constant flow rate pump on a connection line to connect the mixing tank to the supply tank.

17. The method of claim 16, wherein supplying the first solution to the supply tank includes terminating supplying the first solution, when a total amount of the first solution supplied to the supply tank reaches a predetermined amount.

18. The method of claim 17, further comprising draining the chemicals from the mixing tank, when the total amount of the first solution supplied to the supply tank reaches a predetermined amount.

19. The method of claim 18, wherein producing the first solution includes:
circulating the chemicals along a circulation line connected to the mixing tank; and
measuring and correcting a concentration of the first solution using a concentration meter on the circulation line.

20. The method of claim 19, wherein supplying the first solution to the supply tank is performed when the concentration of the first solution reaches a predetermined concentration range.
